(19) United States
(12) Patent Application Publication
(10) Pub. No.: US 2008/0055957 A1
(43) Pub. Date: Mar. 6, 2008

(54) Three-Dimensional Memory Module (3D-MM) Excelling Contemporary Micro-Drive (CMD)

(76) Inventor: Guobiao ZHANG, Carson City, NV (US)

Correspondence Address: GUOBIAO ZHANG, P.O. BOX 6182, STATELINE, NV, 89449-6182, US

(21) Appl. No.: 11/736,781

(22) Filed: Apr. 18, 2007

Related U.S. Application Data
(60) Provisional application No. 60/767,573, filed on Aug. 30, 2006.

(51) Int. Cl. G11C 5/02

(52) U.S. Cl. 365/51

(57) ABSTRACT

The present invention discloses a three-dimensional memory module (3D-MM), which excels contemporary micro-drive (CMD) in both physical size and storage capacity. Three-dimensional memory (3D-M)-based 3D-MM ((3D)²-MM) further excels CMD in manufacturing cost. Mask-programmable (3D)²-MM is the only semiconductor storage that can store a mobile movie library.

### CROSS-REFERENCE TO RELATED APPLICATIONS

This application is related to U.S. patent application Ser. No. 60/767,573, “Three-Dimensional Memory Module (3D-MM) Excelling Contemporary Micro-Drive (CMD)”, filed Aug. 30, 2006.

### BACKGROUND

1. Technical Field of the Invention

The present invention relates to the field of integrated circuit, and more particularly to semiconductor memory.

2. Related Arts

To satisfy consumer's desire to access as much multimedia contents as possible while on the go, a variety of mobile mass devices are developed. Examples include cellular phone, PDA (personal digital assistant), portable video player (including video games), GPS (global positioning system) receiver and others. Mobile mass storage is used in these devices to store multimedia contents. Examples of mobile mass storage include memory cards, SIM card, or embedded memory. For example, FIG. 1 illustrates a memory card 300 carrying multimedia contents can be inserted into and played by a cellular phone 200.

Mobile mass storage has a huge market. The annual sales of cellular phones alone are expected to pass the one-billion-unit mark by 2008. At present, two technologies are competing for this market: one is semiconductor non-volatile memory (NVM, including flash memory and three-dimensional memory); the other is micro-drive, i.e. 1″ hard-disk drive (HDD).

FIG. 2 is a perspective view of a three-dimensional memory (3D-M). It comprises at least two vertically stacked memory levels 20A, 20B. Each memory level (e.g. 20B) comprises a plurality of word lines (e.g. 40Ba, 40Bb), bit lines (e.g. 50Ba, 50Bb) and memory cells (e.g. 60aa-60bb). These memory cells communicate with the substrate 30 through inter-level connecting vias (e.g. 42a, 42b, 52a, 52b). 3D-M can be categorized into three-dimensional mask-programmable memory (3D-MPM) and three-dimensional electrically-programmable memory (3D-EPM). In 3D-MPM, digital information is defined by photo-masks during manufacturing. In 3D-EPM, users can electrically program the memory. One example of 3D-EPM is antifuse-based one-time-programmable 3D-M. More details on 3D-M are disclosed in U.S. Pat. Nos. 5,835,396, 6,034,882, 6,717,222 and others.

Which technology, non-volatile memory (NVM) or micro-drive, will dominate the mobile mass storage market is a multi-billion-dollar question. One deciding factor is storage capacity. FIG. 3 (Table 1, where “˜” means an estimated value, “?” means it is questionable to scale down to this node) compares the storage capacity between a single NVM chip and a contemporary micro-drive (CMD). Here, CMD refers to the largest micro-drive (in terms of capacity) that is in mass production at the same time as the NVM. At the 50 nm node (in Year 2007), the storage capacity of a 140 mm² flash chip is 2 GB; a 3D-EPM chip at the same node can store three times as much, or ˜6 GB, while 3D-MPM can store eight times as much, or ˜16 GB. On the other hand, contemporary micro-drive (CMD), introduced around Year 2007, can store 8 GB. Apparently, when comparing the storage capacity with CMD, NVM is at disadvantage (except for 3D-MPM). Moreover, towards the 17 nm node (around Year 2020), CMD can be further scaled, while flash and 3D-EPM may not. As a result, the advantage of CMD against NVM will become more evident.

Although NVM is at disadvantage against CMD in storage capacity, it has great advantages in physical size, power consumption and reliability. It is still highly desirable to use NVM for mobile mass storage. Accordingly, the present invention discloses a three-dimensional memory module (3D-MM). It comprises enough vertically stacked NVM chips to excel contemporary micro-drive (CMD) in both physical size and storage capacity.

### OBJECTS AND ADVANTAGES

It is a principle object of the present invention to provide a memory module which excels contemporary micro-drive (CMD) in both physical size and storage capacity.

It is a further object of the present invention to provide a memory module whose physical size is no larger than but storage capacity larger than CMD.

It is a further object of the present invention to provide a memory module whose manufacturing cost is lower than CMD.

It is a further object of the present invention to provide a memory module to store a mobile movie library at a reasonable storage cost per movie.

In accordance with these and other objects of the present invention, a three-dimensional memory module (3D-MM) excelling contemporary micro-drive (CMD) is disclosed.

### SUMMARY OF THE INVENTION

The present invention discloses a three-dimensional memory module (3D-MM), which excels contemporary micro-drive (CMD) in both physical size and storage capacity. This 3D-MM comprises a plurality of vertically stacked memory chips; and, its physical size is no larger than but storage capacity larger than CMD. By convention, a 3D-MM comprising M(≧2) chips is denoted as ×M3D-MM. For example, a ×8 3D-MM comprises eight vertically stacked chips. By stacking memory chips in a direction perpendicular to the substrate (i.e. vertical stacking), the 3D-MM footprint is just slightly larger than a single chip. Moreover, by using thinned chips, the 3D-MM height is small. For example, the height of a ×8 3D-MM can be as small as 1.2 mm. Accordingly, the physical size of the 3D-MM can be easily limited to no larger than CMD, which is 40 mm×30 mm×5 mm.

In a 3D-MM, each memory chip has a storage capacity Sᵢ (i=1, 2, . . . M). The total 3D-MM capacity S_{3D-MM}, which is the sum of the storage capacity of all memory chips in the 3D-MM, should be larger than the CMD capacity S_{CMD}, i.e.

S_{3D-MM}=ΣS_{i(i=1, 2, . . . M)}>S_{CMD}.

### If all memory chips are the same, the total number of chips M in the 3D-MM should be larger than the quotient of the CMD capacity S_{CMD} and the NVM chip capacity S_{NVM}, i.e.

M>S_{CMD}/S_{NVM}.

One 3D-MM of great interest is 3D-M-based 3D-MM, i.e. (3D)²-MM. (3D)²-MM is a 3D-MM comprising a plurality of vertically stacked 3D-M chips. Its storage capacity is maximized by first stacking multiple memory levels in a 3D-M chip and then stacking multiple memory chips in a 3D-MM module. According to TABLE 2, (3D)²-MM needs at most 2 chips to excel CMD in storage capacity. With such a small number of chips, the manufacturing cost of a (3D)²-MM could be as low as ˜$20, much less than ˜$50 of the CMD. In sum, (3D)²-MM excels CMD not only in physical size and storage capacity, but also in manufacturing cost.

One (3D)²-MM with very large capacity is mask-programmable (3D)²-MM, or 3D-MPM-based 3D-MM, i.e. (3D)²-MPMM. (3D)²-MPMM is a 3D-MM comprising a plurality of vertically stacked 3D-MPM chips. Note that even a single 3D-MPM chip has a larger storage capacity than CMD. The purpose of 3D-stacking here is not to excel CMD, but to provide an extremely large storage medium for mobile multimedia library (MML), particularly for mobile movie library (MmL). Another advantage of the (3D)²-MPMM is that its average storage cost per movie is comparable to the conventional means. In the conventional means, DVD is used to distribute movies and its average storage cost per movie ranges from $0.30 to $0.70. At the 50 nm node, a ×4 (3D)²-MPMM can store ˜64 GB, or ˜120 movies, with an average storage cost per movie ˜0.40. Two to three such modules are adequate to store any genre of movies at Movielink (www.movielink.com, referring to FIG. 19). At the 17 nm node, a ×8 (3D)²-MPMM can store ˜1 TB, enough for all movies at Movielink, with an average storage cost per movie ˜0.05. This is unimaginable for any of the existing semiconductor storage technologies.

Besides 3D-M chips, a (3D)²-MM may comprise other type(s) of IC chip(s). Accordingly, the present invention discloses a combo (3D)²-MM. It comprises a plurality of 3D-M chips and at least one non-3D-M chip. One combo (3D)²-MM of great interest is mixed (3D)²-MM, which comprises at least one logic/analog chip (Here, “/” means “and or” relationship). The logic/analog chip processes information stored in 3D-M chips. Another combo (3D)²-MM of great interest is hybrid (3D)²-MM, which comprises a plurality of 3D-M chips and at least one memory chip of second type, e.g. a flash memory, or 3D-EPM. Hybrid (3D)²-MM enables a low-cost multimedia storage with content upgradeability.

### BRIEF DESCRIPTION OF THE DRAWINGS

FIG. 1 illustrates a cellular phone with a memory card;

FIG. 2 is a perspective view of a three-dimensional memory (3D-M);

FIG. 3 (TABLE 1) compares the storage capacity between a single non-volatile memory (NVM) chip and contemporary micro-drive (CMD);

FIG. 4 (TABLE 2) lists the minimum number of NVM chips in a 3D-MM to excel contemporary micro-drive (CMD);

FIGS. 5A-5B are perspective and z-x cross-sectional views of a preferred offset 3D-MM;

FIGS. 6A-6B are z-x cross-sectional and top views of a preferred rotated 3D-MM;

FIG. 7 is a cross-sectional view of a preferred spacer-separated 3D-MM;

FIG. 8 is a cross-sectional view of a preferred flip-bonded 3D-MM;

FIG. 9 is a cross-sectional view of a preferred hybrid-bonded 3D-MM;

FIG. 10 is a cross-sectional view of a preferred through-silicon via-based 3D-MM;

FIGS. 11A-11B are z-x cross-sectional and y-z side views of a preferred edge-contact-based 3D-MM;

FIG. 12 is a cross-sectional view of a preferred double-sided flip-bonded 3D-MM;

FIG. 13 is a cross-sectional view of a preferred double-sided wire-bonded 3D-MM;

FIG. 14 is a cross-sectional view of a first preferred package-stacked 3D-MM;

FIG. 15 is a cross-sectional view of a second preferred package-stacked 3D-MM;

FIG. 16 is a cross-sectional view of a preferred 3D-M-based 3D-MM (i.e. (3D)²-MM);

FIG. 17 is a cross-sectional view of a preferred three-dimensional mask-programmable memory (3D-MPM);

FIG. 18 (TABLE 3) lists the storage capacity of (3D)²-MM;

FIG. 19 (TABLE 4) lists number of movies in each genre at Movielink (http://www.movielink.com), and number of ×8 (3D)²-MPMM required to store them at the 50 nm and 17 nm nodes;

FIG. 20 is a cross-sectional view of a preferred mixed (3D)²-MM;

FIG. 21 is a cross-sectional view of a preferred hybrid (3D)²-MM.

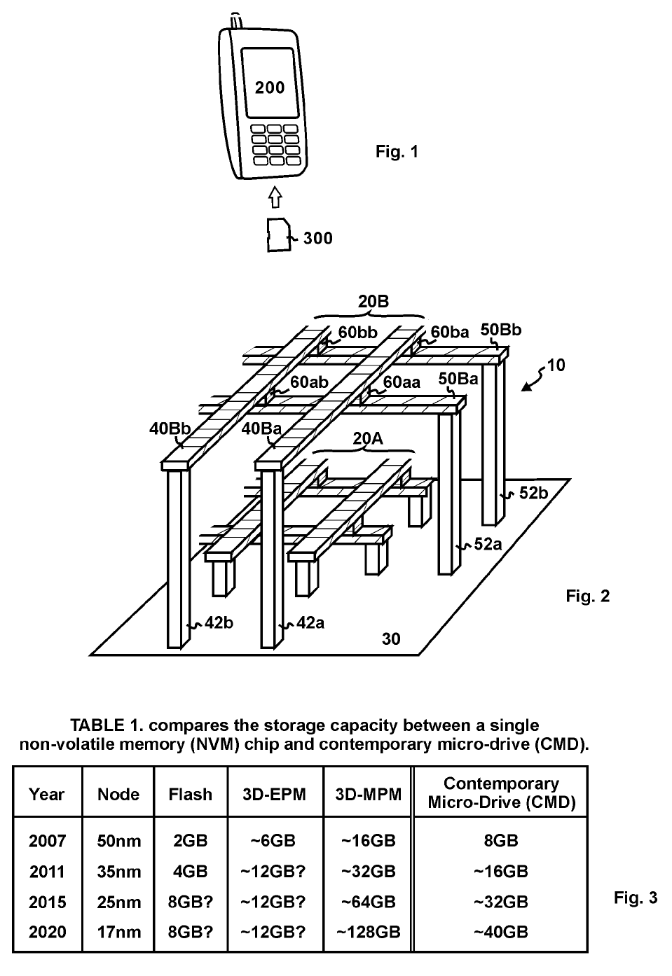

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention discloses a three-dimensional memory module (3D-MM), which excels contemporary micro-drive (CMD) in both physical size and storage capacity. This 3D-MM comprises a plurality of vertically stacked memory chips; and, its physical size is no larger than but storage capacity larger than CMD. By convention, a 3D-MM comprising M(≧2) chips is denoted as ×M3D-MM. For example, a ×8 3D-MM comprises eight vertically stacked chips. By stacking memory chips in a direction perpendicular to the substrate (i.e. vertical stacking), the 3D-MM footprint is just slightly larger than a single chip. Moreover, by using thinned chips, the 3D-MM height is small. For example, the height of a ×8 3D-MM can be as small as 1.2 mm. Accordingly, the physical size of the 3D-MM can be easily limited to no larger than CMD, which is 40 mm×30 mm×5 mm.

In a 3D-MM, each memory chip has a storage capacity Sᵢ (i=1, 2, . . . M). The total 3D-MM capacity S_{3D-MM}, which is the sum of the storage capacity of all memory chips in the 3D-MM, should be larger than the CMD capacity S_{CMD}, i.e.

S_{3D-MM}=ΣS_{i(i=1, 2, . . . M)}>S_{CMD}. (1)

### If all memory chips are the same, the total number of chips M in the 3D-MM should be larger than the quotient of the CMD capacity S_{CMD} and the NVM chip capacity S_{NVM}, i.e.

M>S_{CMD}/S_{NVM}. (2)

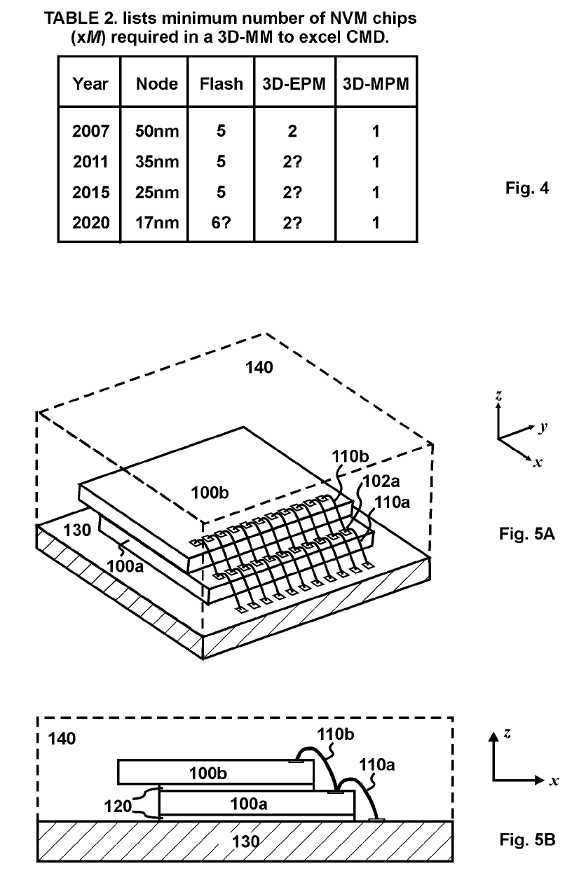

FIG. 4 (TABLE 2) lists the minimum number of NVM chips in a 3D-MM to excel contemporary micro-drive (CMD). Because semiconductor memory scales at a speed comparable to magnetic-disk storage, this number does not change much across technology nodes of interest: flash memory needs 5-6 chips to excel CMD, 3D-EPM needs 2 chips and 3D-MPM needs just 1 chip (or, no 3D-stacking is needed).

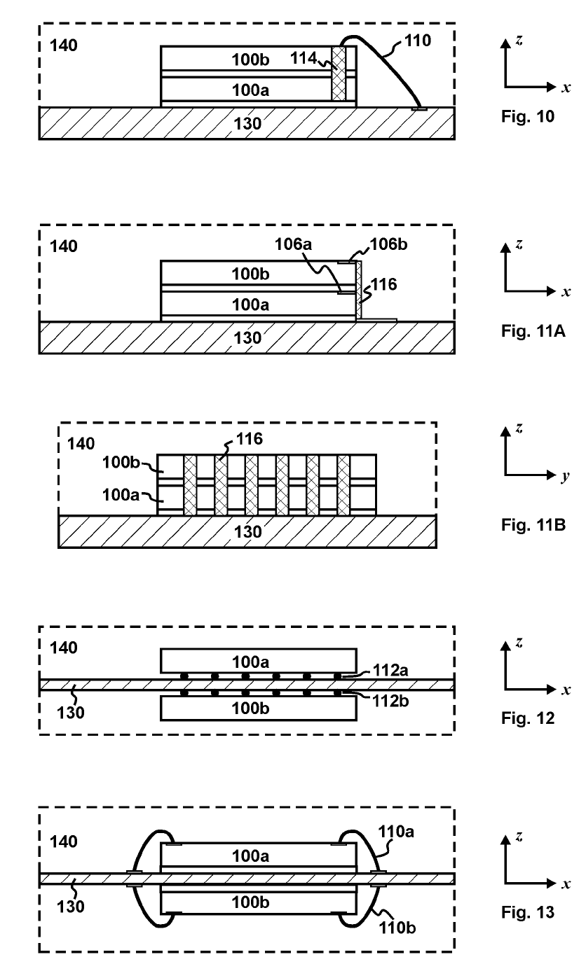

FIGS. 5-13 illustrate several preferred chip-stacked 3D-MM. They can be categorized into: single-sided (FIGS. 5-11B), double-sided (FIGS. 12-13); wire-bonded (FIGS. 5-7), flip-bonded (FIG. 8), hybrid-bonded (FIG. 9); through-silicon via-based (FIG. 10), edge-contact-based (FIGS. 11A-11B). It should be apparent to those skilled in the art that, besides these configurations, other 3D-MM configurations may also be possible, e.g. chip-in-polymer. More details on chip-stacking (also referred to as die-stacking) can be found in the article “Future ICs Go Vertical”, by P. Garrou, Semiconductor International, February 2005.

Referring to FIGS. 5A-5B, a preferred offset 3D-MM is illustrated. It comprises two memory chips 100a, 100b. The active circuits of both chips 100a, 100b face upward (i.e. along +z direction). Chip 100a is attached to substrate 130 by adhesive layer 120. The substrate 130 may comprise, for example, a printed circuit board (PCB), a memory card, a lead frame, tape automated bonding (TAB) tape or other substrate. Chip 100b is stacked on chip 100a and is offset along −x direction relative to chip 100a in such a way that contact pads 102a on chip 100a are exposed. As a result, chip 100a can make electrical connection to chip 100b and/or substrate 130 through bond wires 110b, 110a. The stacked chips 100a, 100b are preferably encapsulated in a protective package 140, such as in a molding compound.

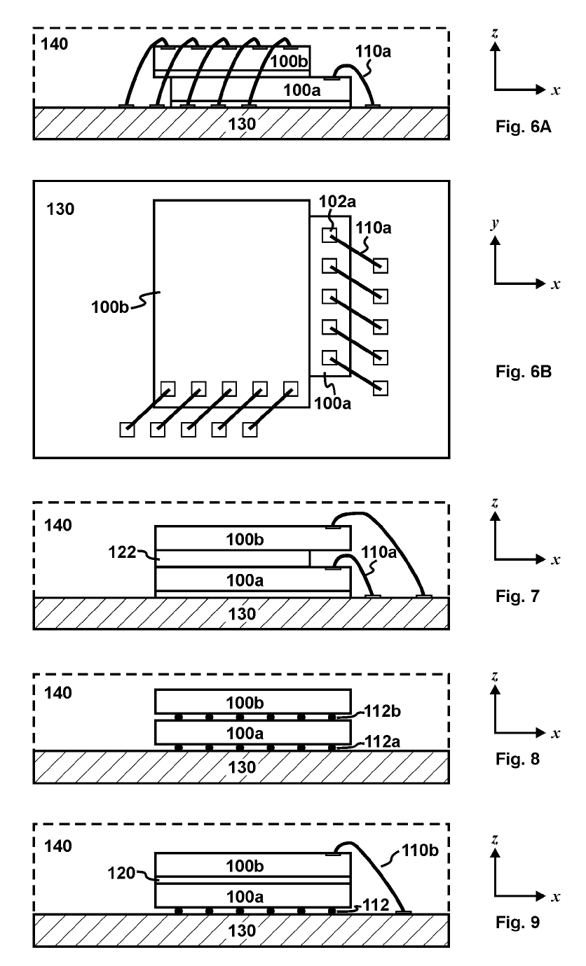

Referring now to FIGS. 6A-6B, a preferred rotated 3D-MM is illustrated. Instead of offsetting as in FIGS. 5A-5B, the top chip 100b is rotated around +z axis in such a way that contact pads 102a on chip 100a are exposed. As a result, chip 100a can make electrical connection to chip 100b and/or substrate 130.

Referring now to FIG. 7, a preferred spacer-separated 3D-MM is illustrated. In this preferred embodiment, chips 100a, 100b are separated by a spacer 122 to such an extent that bondwire loop-height can be accommodated. As a result, chip 100a can make electrical connection to chip 100b and/or substrate 130.

Referring now to FIG. 8, a preferred flip-bonded 3D-MM is illustrated. Different from FIGS. 5-7, the active circuits of these chips 100a, 100b face downward (i.e. along −z direction). Chips 100b, 100a are respectively connected to chip 100a and substrate 130 by solder balls 112b, 112a.

Referring now to FIG. 9, a preferred hybrid-bonded 3D-MM is illustrated. Its top chip 100b has its active circuits facing upward (i.e. along +z direction) and uses bond wires to make electrical connection with substrate 130. On the other hand, its bottom chip 100a has its active circuits facing downward (i.e. along −z direction) and uses solder balls to make electrical connection with substrate 130.

Referring now to FIG. 10, a preferred through-silicon via-based 3D-MM is illustrated. The active circuits of both chips 100a, 100b face the same direction (either both upward or both downward). Through-silicon vias 114 penetrate through stacked chips 110a, 110b and connect them from inside. As a result, chips 100a, 100b make electrical connection to the substrate 130.

Referring now to FIGS. 11A-11B, a preferred edge-contact-based 3D-MM is illustrated. The chips 100a, 100b are aligned and stacked. The stack is then lapped until the contact pads 106b, 106a are exposed. After that, bus metallization 116 is deposited to the side of the stack and interconnects the chips 100b, 100a with the substrate 130.

In FIGS. 5-11, all chip stacks are located on one side of the substrate 130. In FIGS. 12 and 13, chips are located on both sides of the substrate 130. The preferred embodiment in FIG. 12 uses flipchip-bonding, while the preferred embodiment in FIG. 13 uses wire-bonding.

Referring now to FIG. 12, a preferred double-sided flip-bonded 3D-MM is illustrated. Chip 100a has its active circuits facing downward (i.e. along −z direction) and makes electrical connection with the substrate 130 by solder balls 112a. On the other hand, chip 100b is located on the other side of the substrate 130 and has its active circuits facing upward (i.e. along +z direction). It makes electrical connection with the substrate 130 by solder balls 112b.

Referring now to FIG. 13, a preferred double-sided wire-bonded 3D-MM is illustrated. Chip 100a has its active circuits facing upward (i.e. along +z direction) and makes electrical connection with the substrate 130 by bond wires 110a. On the other hand, chip 100b is located on the other side of the substrate 130 and has its active circuits facing downward (i.e. along −z direction). It makes electrical connection with the substrate 130 by bond wire 110b.

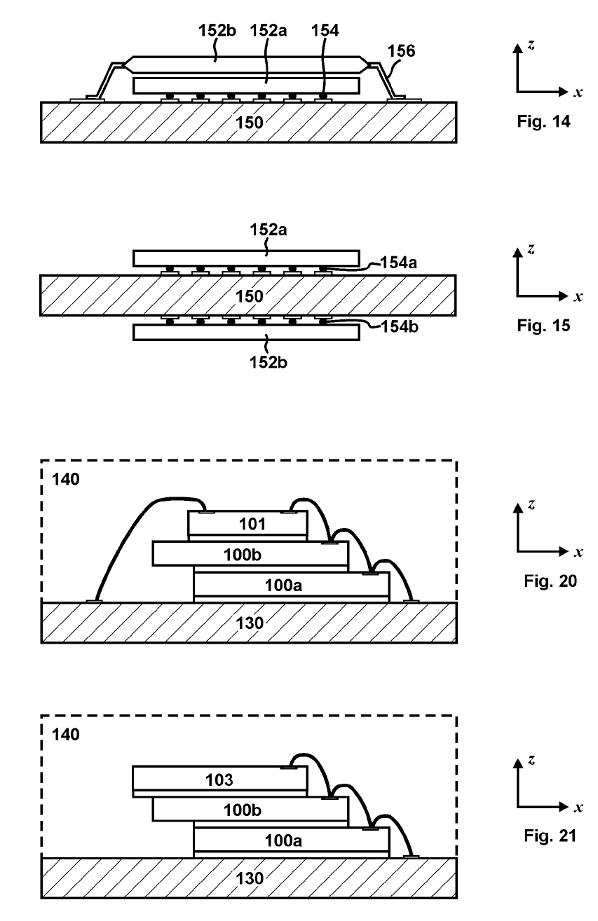

FIGS. 14-15 illustrate two preferred package-stacked 3D-MMs. In FIG. 14, the preferred package-stacked 3D-MM comprises two memory packages 152a, 152b. The first package 152a is flip-bonded to the substrate 150 by solder balls 154. The second package 152b is located above the first package 152a and is surface mounted on the substrate 150 by long gull-wing leads 156. Each package 152a, 152b may also comprise a number of vertically stacked chips. In FIG. 15, the preferred package-stacked 3D-MM also comprises two memory packages 152a, 152b. The first one 152a is flip-bonded to the substrate 150 by solder balls 154a, while the second one 152b is flip-bonded to the other side of the substrate 150 by solder balls 154b. It should be apparent to those skilled in the art that other package-stacking configurations can also be used.

One 3D-MM of great interest is 3D-M-based 3D-MM, i.e. (3D)²-MM. (3D)²-MM is a 3D-MM comprising a plurality of vertically stacked 3D-M chips. Its storage capacity is maximized by first stacking multiple memory levels in a 3D-M chip and then stacking multiple memory chips in a 3D-MM module. According to TABLE 2, (3D)²-MM needs at most 2 chips to excel CMD in storage capacity. With such a small number of chips, the manufacturing cost of a (3D)²-MM could be as low as ˜$20, much less than ˜$50 of the CMD. In sum, (3D)²-MM excels CMD not only in physical size and storage capacity, but also in manufacturing cost.

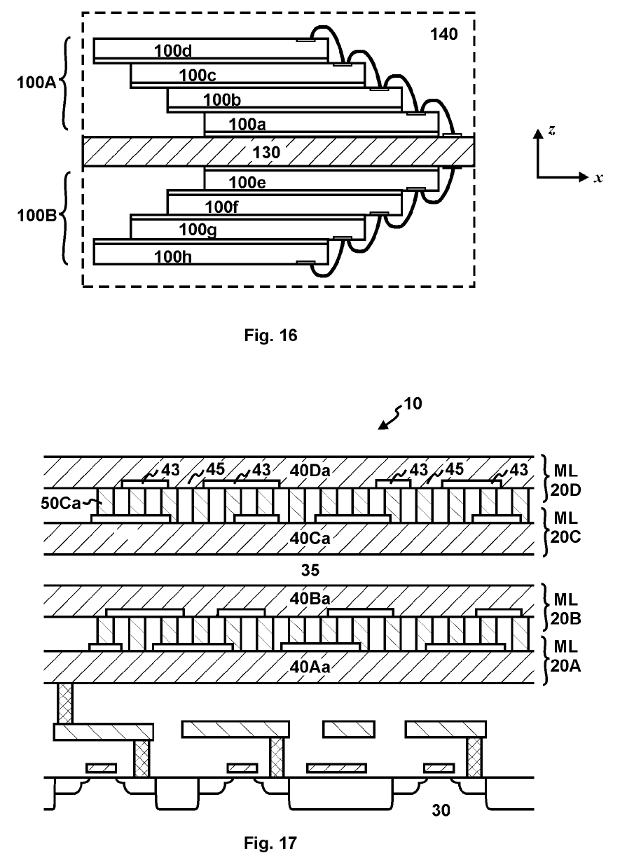

One (3D)²-MM with very large capacity is mask-programmable (3D)²-MM, or 3D-MPM-based 3D-MM, i.e. (3D)²-MPMM. (3D)²-MPMM is a 3D-MM comprising a plurality of vertically stacked 3D-MPM chips. Note that even a single 3D-MPM chip has a larger storage capacity than CMD. The purpose of 3D-stacking here is not to excel CMD, but to provide an extremely large storage medium for mobile multimedia library (MML), particularly for mobile movie library (MmL). FIGS. 16-17 illustrate a preferred ×8 (3D)²-MPMM module and its 3D-MPM chip.

In FIG. 16, the preferred ×8 (3D)²-MPMM comprises eight vertically stacked 3D-MPMM chips 100a-100h. Being double-sided (referring to FIGS. 12-13), it has a chip-stack (100A, 100B) on each side of the substrate 130. Each chip-stack (100A, 100B) is an offset 3D-MM (referring to FIGS. 5A-5B) comprising four vertically stacked chips (100a-100d, or 100e-100h). Apparently, besides offset 3D-MM, other 3D-MM configurations may also be used in each chip-stack.

In FIG. 17, the preferred 3D-MPM 10 comprises four vertically stacked memory levels 20A-20D. These memory levels are further stacked above a substrate 30. Each memory level (e.g. 20D) comprises word lines (e.g. 40Da), bit lines (e.g. 50Ca) and info-dielectric 43. The existence or absence of openings 45 in the info-dielectric 43 determines the information stored in memory cells.

This preferred embodiment uses a number of ways to increase the storage capacity and lower the manufacturing cost, including: 1) nF-opening (n>1), i.e. the dimension of the opening 45 is larger than the width F of the address line (e.g. 50Ca) (referring to U.S. Pat. No. 6,903,427); 2) N-ary MPM (N>2), i.e. each MPM cell has N possible states and stores more than one bit (referring to U.S. patent application Ser. No. 11/162,262); 3) hybrid-level 3D-M, i.e. some adjacent memory levels share address lines (e.g. memory levels 20C, 20D share address line 50Ca), while other adjacent memory levels do not (e.g. memory levels 20B, 20C are separated by an inter-level dielectric 35) (referring to China, P.R. Patent Application 200610162698.2).

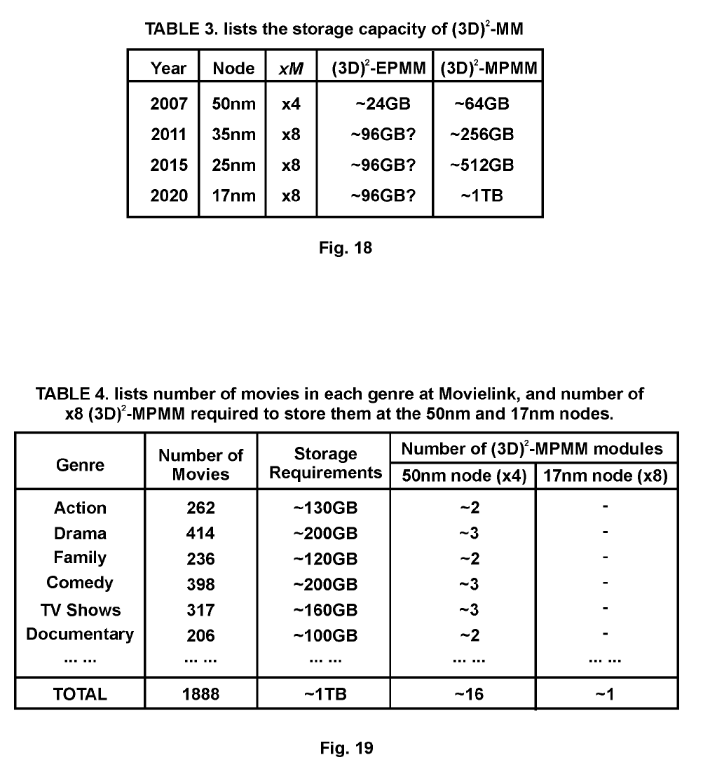

With each movie occupying ˜500 MB space, an MmL containing even 100 movies requires 50 GB space. Furthermore, the average storage cost per movie should be small, preferably comparable to the conventional means. In the conventional means, DVD is used to distribute movies and its average storage cost per movie ranges from $0.30 to $0.70. Among all semiconductor storage technologies, (3D)²-MPMM has the largest storage capacity (FIG. 18/Table 3) and is the only one that meet these requirements. Its average storage cost per movie is comparable to the conventional means, i.e. DVD. For example, at the 50 nm node, a ×4 (3D)²-MPMM can store ˜64 GB, or 120 movies, with average storage cost per movie ˜0.40; at the 17 nm node, a ×8 (3D)²-MPMM can store ˜1 TB, enough for all movies at Movielink (FIG. 19/Table 4), with average storage cost per movie ˜0.05. This is unimaginable for any of the existing semiconductor storage technologies.

Besides 3D-M chips, a (3D)²-MM may comprise other type(s) of IC chip(s). Accordingly, the present invention discloses a combo (3D)²-MM. It comprises a plurality of 3D-M chips and at least one non-3D-M chip. One combo (3D)²-MM of great interest is mixed (3D)²-MM, which comprises at least one logic/analog chip (Here, “/” means “and or” relationship). Another combo (3D)²-MM of great interest is hybrid (3D)²-MM, which comprises a plurality of 3D-M chips and at least one memory chip of second type, e.g. a flash memory chip.

FIG. 20 illustrates a preferred mixed (3D)²-MM. It comprises two 3D-M chips 100a, 100b and one logic/analog chip 101. They are stacked on top of each other. The logic/analog chip 101 processes information stored in the 3D-M chips 100a, 100b. It could be a memory controller, which formats the (3D)²-MM outputs to one of the IEEE standards, e.g. CF-format, SD-format. It may also comprises a decryptor, a decoder and a digital-to-analog (D/A) converter. The logic/analog chip 101 decrypts the contents, decodes them and further converts them into analog outputs. Because the content outputs are analog and difficult to make a perfect “digital” copy, this mixed 3D-MM provides excellent copyright protection to its contents. More details on copyright protection are disclosed in the co-pending U.S. patent application Ser. No. 10/906,609, “Tamper-proof content-playback system offering excellent copyright protection”.

From TABLE 1, it can be observed that from flash to 3D-MPM, the chip capacity increases (3× from flash to 3D-EPM, 8× from flash to 3D-MPM), but memory writability degrades (re-writable for flash, write-once for 3D-EPM and no-write for 3D-MPM). In order to have a balanced capacity and writability, the present invention further discloses a hybrid (3D)²-MM. As illustrated in FIG. 21, this preferred hybrid (3D)²-MM comprises two 3D-M chips 100a, 100b and a memory chip of second type 103. The 3D-MPM chips 100a, 100b provide a large capacity at low cost. The memory chip of second type 103 could be flash memory or 3D-EPM, which guarantees writability. Hybrid (3D)²-MM enables a low-cost multimedia storage with content upgradeability.

While illustrative embodiments have been shown and described, it would be apparent to those skilled in the art that may more modifications than that have been mentioned above are possible without departing from the inventive concepts set forth therein. For example, 3D-MM and (3D)²-MM can store not only movies, but also textual contents (e.g. books), audio contents (e.g. songs), image contents (e.g. GPS maps, photos), and other video contents (e.g. video clips). The invention, therefore, is not to be limited except in the spirit of the appended claims.

What is claimed is:

1. A three-dimensional memory module (3D-MM) excelling contemporary micro-drive (CMD), comprising:
a plurality of vertically stacked memory chips;
wherein the sum of the storage capacity of all memory chips in said 3D-MM is larger than said CMD and the physical size of said 3D-MM is no larger than said CMD.

2. The 3D-MM according to claim 1, wherein all memory chips in said 3D-MM are the same, and the total number of memory chips in said 3D-MM is larger than the quotient of the CMD capacity and the NVM chip capacity.

3. The 3D-MM according to claim 1, wherein at least one of said memory chips is a three-dimensional memory (3D-M).

4. The 3D-MM according to claim 3, wherein said 3D-M comprises a three-dimensional mask-programmable memory (3D-MPM).

5. The 3D-MM according to claim 3, wherein said 3D-M comprises a three-dimensional electrically-programmable read-only memory (3D-EPM).

6. The 3D-MM according to claim 1, wherein said 3D-MM is an offset 3D-MM.

7. The 3D-MM according to claim 1, wherein said 3D-MM is a rotated 3D-MM.

8. The 3D-MM according to claim 1, wherein said 3D-MM is a spacer-separated 3D-MM.

9. The 3D-MM according to claim 1, wherein said 3D-MM is a single-sided 3D-MM.

10. The 3D-MM according to claim 1, wherein said 3D-MM is a double-sided 3D-MM.

11. The 3D-MM according to claim 1, wherein said 3D-MM is a wire-bonded 3D-MM.

12. The 3D-MM according to claim 1, wherein said 3D-MM is a flip-bonded 3D-MM.

13. The 3D-MM according to claim 1, wherein said 3D-MM is a hybrid-bonded 3D-MM.

14. The 3D-MM according to claim 1, wherein said 3D-MM is a through-silicon via-based 3D-MM.

15. The 3D-MM according to claim 1, wherein said 3D-MM is an edge-contact-based 3D-MM.

16. The 3D-MM according to claim 1, further comprising: a plurality of vertically stacked memory packages.

17. The 3D-MM according to claim 1, further comprising a flash memory.

18. The 3D-MM according to claim 1, further comprising a logic/analog chip.

19. The 3D-MM according to claim 1, wherein said 3D-MM stores a mobile multimedia library.

20. The 3D-MM according to claim 19, wherein said mobile multimedia library comprises a mobile movie library.
